(19) United States
(12) Patent Application Publication
(10) Pub. No.: US 2023/0395732 A1
(43) Pub. Date: Dec. 7, 2023

(54) SCHOTTKY BARRIER DIODE

(71) Applicants: TAMURA CORPORATION, Tokyo (JP); Novel Crystal Technology, Inc., Saitama (JP)

(72) Inventors: Shinya YAMAGUCHI, Saitama (JP); Akio TAKATSUKA, Saitama (JP)

(73) Assignees: TAMURA CORPORATION, Tokyo (JP); Novel Crystal Technology, Inc., Saitama (JP)

(21) Appl. No.: 18/327,538

(22) Filed: Jun. 1, 2023

(30) Foreign Application Priority Data
Jun. 1, 2022 (JP) 2022-089615
May 25, 2023 (JP) 2023-085945

(51) Int. Cl. H01L 29/872; H01L 29/47; H01L 29/24

(52) U.S. Cl. CPC H01L 29/872; H01L 29/24; H01L 29/47

(57) ABSTRACT

A Schottky barrier diode includes an n-type semiconductor layer including a gallium oxide-based semiconductor, an insulating film including SiO₂ and covering a portion of an upper surface of the n-type semiconductor layer, and an anode electrode which is connected to the upper surface of the n-type semiconductor layer to form a Schottky junction with the n-type semiconductor layer and at least a portion of an edge of which is located on the insulating film. The insulating film further includes a first layer in contact with the n-type semiconductor layer and a second layer on the first layer. A refractive index of the first layer is lower than a refractive index of the second layer.

### CROSS-REFERENCE TO RELATED APPLICATIONS

The present patent application claims the priority of Japanese patent application Nos. 2022/089615 and 2023/085945 filed on Jun. 1, 2022 and May 25, 2023, respectively, and the entire contents of Japanese patent application Nos. 2022/089615 and 2023/085945 are hereby incorporated by reference.

### TECHNICAL FIELD

The present invention relates to a Schottky barrier diode.

### BACKGROUND ART

A Schottky barrier diode is known which has a semiconductor layer formed of a Ga₂O₃-based single crystal and has a field-plate structure to relax electric field concentration at an end portion of an anode electrode (see Patent Literature 1).

The Schottky barrier diode described in Patent Literature 1 is provided with an insulation layer which is formed of an insulating material such as SiO₂ and is provided on a semiconductor layer, and an anode electrode which is in Schottky contact with the semiconductor layer in an opening of the insulation layer and has a field plate overlying the insulation layer in a region around the opening.

### CITATION LIST

### Patent Literature

Patent Literature 1: JP 2017/45969A

### SUMMARY OF INVENTION

An insulating film provided on a semiconductor layer, such as the insulation layer in the Schottky barrier diode described in Patent Literature 1, also acts as a passivation film that suppresses surface leakage current flowing along the upper surface of the semiconductor layer. However, as a result of intensive study, the inventors of the present invention have found that, particularly when the semiconductor layer is formed of a gallium oxide-based semiconductor and a SiO₂ film is used as the insulating film on the semiconductor layer, there may be a problem that increasing the density of the insulating film causes an increase in surface leakage due to damage to the semiconductor layer during film formation, while decreasing the density of the insulating film causes a decrease in dielectric withstand voltage due to poor film quality.

It is an object of the invention to provide a Schottky barrier diode which includes a semiconductor layer formed of a gallium oxide-based semiconductor and a passivation film formed of SiO₂ to significantly suppress the surface leakage and significantly enhance the dielectric withstand voltage.

An aspect of the invention provides a Schottky barrier diode defined by (1) to (3) below.
(1) A Schottky bather diode, comprising:
   an n-type semiconductor layer comprising a gallium oxide-based semiconductor;
   an insulating film comprising SiO₂ and covering a portion of an upper surface of the n-type semiconductor layer; and
   an anode electrode which is connected to the upper surface of the n-type semiconductor layer to form a Schottky junction with the n-type semiconductor layer and at least a portion of an edge of which is located on the insulating film,
   wherein the insulating film further comprises a first layer in contact with the n-type semiconductor layer and a second layer on the first layer, and
   wherein a refractive index of the first layer is lower than a refractive index of the second layer.
(2) The Schottky bather diode defined by (1), wherein the refractive index of the first layer is not more than 1.44, and wherein the refractive index of the second layer is not less than 1.46.
(3) The Schottky bather diode defined by (1) or (2), wherein side surfaces of the first and second layers of the insulating film on the anode electrode side are inclined so as to face obliquely upward.

### ADVANTAGEOUS EFFECTS OF INVENTION

According to an aspect of the invention, it is possible to provide a Schottky bather diode which includes a semiconductor layer formed of a gallium oxide-based semiconductor and a passivation film formed of SiO₂ to significantly suppress the surface leakage and significantly enhance the dielectric withstand voltage.

### BRIEF DESCRIPTION OF DRAWINGS

FIGS. 1A and 1B are vertical cross-sectional views showing Schottky bather diodes in an embodiment of the present invention.

FIGS. 2A and 2B are vertical cross-sectional views showing MOS diodes used to examine effects of an insulating film of the Schottky bather diode.

FIGS. 3A and 3B are graphs showing changes in current density when a forward electric field is applied to the MOS diodes.

FIGS. 4A and 4B are graphs showing changes in current density when reverse voltage is applied to the MOS diodes.

### DESCRIPTION OF EMBODIMENTS

### Configuration of a Schottky Barrier Diode

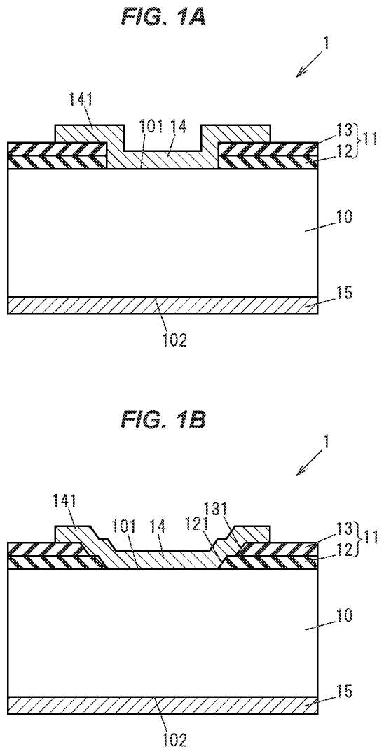

FIG. 1A is a vertical cross-sectional view showing a Schottky barrier diode 1 in an embodiment. The Schottky barrier diode 1 is a vertical Schottky barrier diode that includes a semiconductor layer formed of a gallium oxide-based semiconductor.

The Schottky barrier diode 1 includes an n-type semiconductor layer 10 formed of a gallium oxide-based semiconductor, an insulating film 11 formed of SiO₂ and covering a portion of an upper surface 101 of the n-type semiconductor layer 10, and an anode electrode 14 which is connected to the upper surface 101 of the n-type semiconductor layer 10 to form a Schottky junction with the n-type semiconductor layer and at least a portion of an edge of which is located on the insulating film 11. The insulating film 11 includes a first layer 12 in contact with the n-type semiconductor layer 10 and a second layer 13 on the first layer 12, and a refractive index of the first layer 12 is lower than a refractive index of the second layer 13. In addition, a cathode electrode 15 is connected to a lower surface 102 of the n-type semiconductor layer 10 which is a surface on the opposite side to the upper surface 101.

In the Schottky barrier diode 1, an energy barrier at an interface between the anode electrode 14 and the n-type semiconductor layer 10 as viewed from the n-type semiconductor layer 10 is lowered by applying forward voltage between the anode electrode 14 and the cathode electrode 15, allowing a current to flow from the anode electrode 14 to the cathode electrode 15. On the other hand, when reverse voltage is applied between the anode electrode 14 and the cathode electrode 15, the current does not flow due to the Schottky barrier.

The n-type semiconductor layer 10 is formed of a single crystal of a gallium oxide-based semiconductor having a β-crystal structure. The gallium oxide-based semiconductor here means Ga₂O₃ or means Ga₂O₃ doped with an element such as Al or In. The gallium oxide-based semiconductor has a composition represented by, e.g., (GaₓAl_{y}In_{(1-x-y)})₂O₃ (0<x≤1, 0≤y≤1, 0<x+y≤1). Ga₂O₃ has a wider band gap when doped with Al and a narrower band gap when doped with In.

The n-type semiconductor layer 10 contains a donor impurity such as Si or Sn. A donor concentration in the n-type semiconductor layer 10 is, e.g., not less than 1×10¹⁵ cm⁻³ and not more than 1×10¹⁷ cm⁻³. A thickness of the n-type semiconductor layer 10 is, e.g., not less than 2 μm and not more than 100 μm. The n-type semiconductor layer 10 is formed of, e.g., a substrate cut out of a single crystal grown by a liquid phase growth method.

The n-type semiconductor layer 10 may be a stacked body composed of plural semiconductor layers, and may be, e.g., composed of a substrate and an epitaxial layer epitaxially grown thereon.

In the Schottky barrier diode 1, at least a portion of the edge of the anode electrode 14 is placed on the insulating film 11 as described above. A portion 141 of the edge of the anode electrode 14, which is placed on the insulating film 11, is called a field plate, and a structure including the field plate is called a field-plate structure. By providing such a field-plate structure, it is possible to relax electric field concentration in the vicinity of the end portion of the anode electrode 14 and improve dielectric withstand voltage of the Schottky barrier diode 1.

To significantly improve the dielectric withstand voltage by the field-plate structure, it is preferable that the edge of the anode electrode 14 be placed on the insulating film 11 all around the perimeter. When, e.g., the planar shape of the insulating film 11 is an annular shape surrounding a junction between the n-type semiconductor layer 10 and the anode electrode 14, the planar shape of the portion 141 placed on the insulating film 11 is also an annular shape.

The insulating film 11 is formed using plasma CVD capable of relatively good film formation at low temperature. The first layer 12 and the second layer 13, which constitute the insulating film 11 and have different refractive indices, can be formed differently from each other by controlling plasma power. The insulating film 11 is formed on the entire upper surface 101 of the n-type semiconductor layer 10, and is then patterned to expose a region of the upper surface 101 to which the anode electrode 14 is connected.

In general, the higher the density of the insulating film on which the field plate is placed, the greater the improvement in dielectric withstand voltage of the Schottky barrier diode. Increasing the plasma power of the plasma CVD can increase the density of the insulating film but also causes more damage to the upper surface of the semiconductor layer during film formation. As the damage increases, the interface state density on the upper surface of the semiconductor layer increases, hence, a leakage current flowing at the interface between the semiconductor layer and the insulating film (hereinafter, referred to as interface leakage current) increases. On the other hand, decreasing the plasma power of the plasma CVD can suppress damage to the upper surface of the semiconductor layer and thereby suppress an increase in the interface leakage current but causes a decrease in the density of the insulating film, hence, the dielectric withstand voltage of the Schottky barrier diode cannot be significantly improved.

In the Schottky barrier diode 1 of the embodiment of the invention, the insulating film 11 includes the first layer 12 in contact with the n-type semiconductor layer 10 and the second layer 13 on the first layer 12, and the refractive index of the first layer 12 is lower than the refractive index of the second layer 13, as described above. Here, there is a correlation between the density and the refractive index for the insulating film 11, where the higher the density, the higher the refractive index.

Thus, the first layer 12 is formed under conditions that plasma power is lower than that for the second layer 13. By forming the first layer 12 in contact with the n-type semiconductor layer 10 under the conditions of low plasma power, it is possible to suppress the damage to the n-type semiconductor layer 10 and suppress the interface leakage current.

Meanwhile, the second layer 13 having a higher refractive index than the first layer 12 has a higher density than the first layer 12. By including the second layer 13 having a high density in the insulating film 11, it is possible to increase the dielectric withstand voltage of the Schottky barrier diode 1. The second layer 13 having a high density is formed under conditions that plasma power of the plasma CVD is high, but damage to the n-type semiconductor layer 10 during film formation of the second layer 13 can be suppressed since the first layer 12 is present under the second layer 13.

That is, by using the insulating film 11 including the first layer 12 and the second layer 13, it is possible to enhance the dielectric withstand voltage of the Schottky barrier diode 1 and suppress the interface leak current.

To significantly suppress damage to the n-type semiconductor layer 10 during film formation of the first layer 12, the refractive index of the first layer 12 is preferably not more than 1.44. To significantly suppress damage to the n-type semiconductor layer 10 during film formation of the second layer 13, a thickness of the first layer 12 is preferably not less than 450 nm.

To significantly improve the dielectric withstand voltage of the Schottky barrier diode 1, the refractive index of the second layer 13 is preferably not less than 1.46 and a thickness of the second layer 13 is preferably not less than 20 nm. Meanwhile, to suppress stress generation, the thickness of the second layer 13 is preferably not more than 2000 nm. Furthermore, it has been observed that the interface leakage current tends to increase when the thickness of the second layer 13 is more than 100 nm, even though the cause has not been identified. Thus, it is particularly preferable that the thickness of the second layer 13 be not more than 100 nm.

FIG. 1B is a vertical cross-sectional view showing the Schottky barrier diode 1 when the inner side surface of the insulating film 11 is inclined. In the Schottky bather diode 1 shown in FIG. 1B, the inner sides of the first layer 12 and the second layer 13 of the insulating film 11, i.e., a side surface 121 and a side surface 131 on the anode electrode 14 side, are inclined so as to face obliquely upward.

When the side surface 121 and the side surface 131 face obliquely upward, the electric field concentration can be relaxed more effectively than when the side surface 121 and the side surface 131 are vertical or face obliquely downward.

By controlling an etching rate of wet etching at the time of patterning the first layer 12 and the second layer 13, the side surface 121 and the side surface 131 can be inclined so as to face obliquely upward. Here, if the first layer 12 and the second layer 13 having different densities are etched under the same conditions, it is difficult to incline both the side surface 121 and the side surface 131 so as to face obliquely upward since the etching rates are different. Therefore, it is required to separately perform the etching of the first layer 12 and the etching of the second layer 13 under different conditions.

After etching the second layer 13, the first layer 12 is etched using a mask larger than the second layer 13. This causes the position of the side surface 121 to be shifted inward relative to the position of the side surface 131, allowing a step to be provided as shown in FIG. 1B. It is thereby possible to relax the electric field concentration further effectively.

It is also possible to control the inclination angles of the side surface 121 and the side surface 131 by controlling the etching rate, etc., of wet etching at the time of patterning the first layer 12 and the second layer 13. To enhance the effect of relaxing electric field concentration, the inclination angles of the side surface 121 and the side surface 131 are preferably not less than 10° from a direction perpendicular to the upper surface 101 of the n-type semiconductor layer 10.

### Evaluation of the Schottky Bather Diode

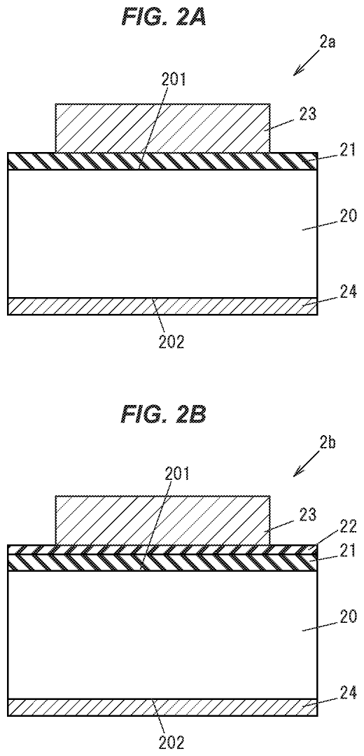

FIGS. 2A and 2B are vertical cross-sectional views showing MOS diodes 2a, 2b used to examine effects of the insulating film 11 of the Schottky barrier diode 1.

The MOS diode 2a shown in FIG. 2A includes an n-type semiconductor layer 20 formed of β-Ga₂O₃, an insulating film 21 formed on an upper surface 201 of the n-type semiconductor layer 20, an electrode 23 formed on the insulating film 21, and an electrode 24 formed on a lower surface 202 of the n-type semiconductor layer 20. The MOS diode 2b shown in FIG. 2B differs from the MOS diode 2a in that an insulating film 22 having a higher refractive index, i.e., a higher density, than the insulating film 21 is formed on the insulating film 21. The insulating films 21 and 22 are formed of SiO₂ and respectively correspond to the first layer 12 and the second layer 13 of the Schottky barrier diode 1.

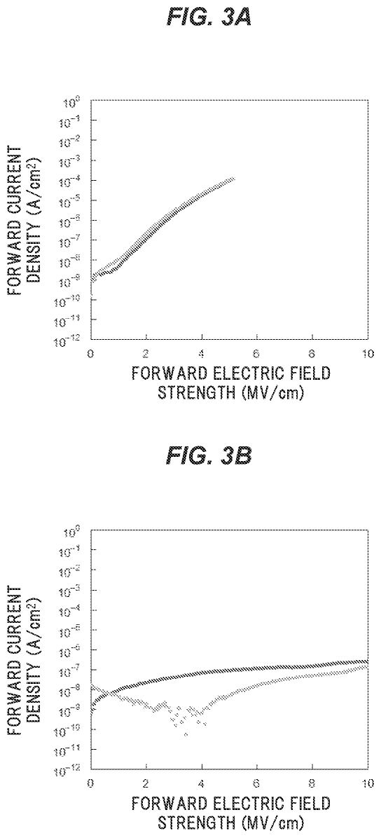

FIG. 3A is a graph showing changes in current density when a forward electric field is applied to the MOS diode 2a having the 300 nm-thick insulating film 21. FIG. 3B is a graph showing changes in current density when a forward electric field is applied to the MOS diode 2b having the 300 nm-thick insulating film 21 and the 50 nm-thick insulating film 22. The results of two measurements conducted each under the same conditions are shown in FIGS. 3A and 3B.

FIGS. 3A and 3B show that the current which flows when an electric field is applied is reduced by using the insulating film 22 corresponding to the second layer 13. This indicates that film quality of the insulating film as a whole is improved by stacking the insulating film 22 on the insulating film 21.

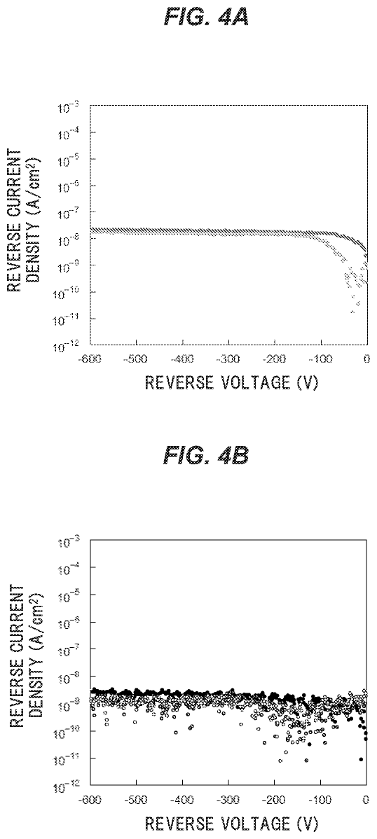

FIG. 4A is a graph showing changes in current density when reverse voltage is applied to the MOS diode 2b having the 300 nm-thick insulating film 21 and the 50 nm-thick insulating film 22. FIG. 4B is a graph showing changes in current density when reverse voltage is applied to the MOS diode 2b having the 450 nm-thick insulating film 21 and the 50 nm-thick insulating film 22. The results of two measurements conducted under the same conditions are shown in FIG. 4A, and the results of three measurements conducted under the same conditions are shown in FIG. 4B.

FIGS. 4A and 4B show that the current which flows when reverse voltage is applied is reduced by increasing the thickness of the insulating film 21 corresponding to the first layer 12. This indicates that increasing the thickness of the insulating film 21 increases the effect of suppressing damage to the upper surface 201 of the n-type semiconductor layer 20 during film formation of the insulating film 22 under the conditions that plasma power of the plasma CVD is high. It is also understood from FIGS. 4A and 4B that this effect is greater when at least the thickness of the insulating film 21 corresponding to the first layer 12 is not less than 450 nm.

### Method for Manufacturing the Schottky Bather Diode

An example of a method for manufacturing the Schottky bather diode 1 will be described below.

Firstly, a gallium oxide-based semiconductor substrate is prepared as the n-type semiconductor layer and ultrasonic cleaning with an organic solvent, hydrofluoric acid cleaning and SPM cleaning, etc., are performed as pre-process cleaning.

Next, SiO₂ films to be the first layer 12 and the second layer 13 of the insulating film 11 are formed on the upper surface 101 by the CVD method. Then, after patterning a resist by photolithography on the upper SiO₂ film to be the second layer 13, wet etching using BHF as an etchant is performed using this resist as a mask, thereby forming the second layer 13 with the inclined side surface 131. Then, after patterning a resist by photolithography on the lower SiOfilm to be the first layer 12, wet etching using BHF as an etchant is performed using this resist as a mask, thereby forming the first layer 12 with the inclined side surface 121.

Next, SPM cleaning and ultrapure water cleaning are performed as pretreatment, and then, a metal film, which is formed of Ni or Pt and is to be the anode electrode 14, is vapor-deposited on the upper surface 101 of the n-type semiconductor layer 10. The metal film is then patterned, thereby forming the anode electrode 14.

Next, the lower surface 102 of the n-type semiconductor layer 10 is covered with a metal film having a Ti/Ni/Au stacked structure, etc., thereby forming the cathode electrode 15.

### Effects of the Embodiment

According to the embodiment, it is possible to provide a Schottky barrier diode which includes a semiconductor layer formed of a gallium oxide-based semiconductor and a passivation film formed of SiO₂ to significantly suppress the surface leakage and significantly enhance the dielectric withstand voltage.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention. In addition, the invention according to claims is not to be limited to the embodiment described above. Further, it should be noted that not all combinations of the features described in the embodiment are necessary to solve the problem of the invention.

### REFERENCE SIGNS LIST

1 SCHOTTKY DIODE
N-TYPE SEMICONDUCTOR LAYER
101 UPPER SURFACE
11 INSULATING FILM
12 FIRST LAYER
121 SIDE SURFACE
13 SECOND LAYER
131 SIDE SURFACE
14 ANODE ELECTRODE
141 PORTION
15 CATHODE ELECTRODE

1. A Schottky bather diode, comprising:
an n-type semiconductor layer comprising a gallium oxide-based semiconductor;
an insulating film comprising SiO₂ and covering a portion of an upper surface of the n-type semiconductor layer; and
an anode electrode which is connected to the upper surface of the n-type semiconductor layer to form a Schottky junction with the n-type semiconductor layer and at least a portion of an edge of which is located on the insulating film,
wherein the insulating film further comprises a first layer in contact with the n-type semiconductor layer and a second layer on the first layer, and
wherein a refractive index of the first layer is lower than a refractive index of the second layer.

2. The Schottky barrier diode according to claim 1, wherein the refractive index of the first layer is not more than 1.44, and wherein the refractive index of the second layer is not less than 1.46.

3. The Schottky barrier diode according to claim 1, wherein side surfaces of the first and second layers of the insulating film on the anode electrode side are inclined so as to face obliquely upward.
